(19) United States
(12) Patent Application Publication
(10) Pub. No.: US 2016/0093345 A1
(43) Pub. Date: Mar. 31, 2016

(54) DYNAMIC RANDOM ACCESS MEMORY TIMING ADJUSTMENTS

(71) Applicant: QUALCOMM Incorporated, San Diego, CA (US)

(72) Inventors: Dexter Tamio Chun, San Diego, CA (US); Michael Drop, San Diego, CA (US); Raghu Sankuratri, San Diego, CA (US)

(21) Appl. No.: 14/497,902

(22) Filed: Sep. 26, 2014

(51) Int. Cl. G11C 7/10

(52) U.S. Cl. CPC G11C 7/1072

(57) ABSTRACT

A method includes detecting, at a controller, a rate-of-change between first data traffic to be sent to a dynamic random access memory (DRAM) at a first time and second data traffic to be sent to the DRAM at a second time. The method also includes adjusting a data rate of the second data traffic in response to a determination that the rate-of-change satisfies a threshold.

### I. FIELD

The present disclosure is generally related to dynamic random access memories (DRAMs).

### II. DESCRIPTION OF RELATED ART

Advances in technology have resulted in smaller and more powerful computing devices. For example, a variety of portable personal computing devices including wireless telephones, such as mobile and smart phones, tablets, and laptop computers, are small, lightweight, and easily carried by users. These devices can communicate voice and data packets over wireless networks. Further, many such devices incorporate additional functionalities such as a digital still camera, a digital video camera, a digital recorder, and an audio file player. Also, such devices can process executable instructions, including software applications, such as a web browser application, that can be used to access the Internet. As such, these devices can include significant computing capabilities.

Electronic devices may include a dynamic random access memory (DRAM) to store data. As a frequency of operation for DRAM devices increases (e.g., as more data is sent to the DRAM during shorter time intervals), timing margins for transferring data between a controller and a DRAM via a DRAM interface may decrease. When a timing margin is violated (e.g., when data is sent and/or received during non-transition periods of a clock cycle), data errors may occur at the DRAM. Violations of the timing margins may be due to physical variations in a semiconductor fabrication process, temperature conditions, and/or voltage conditions (e.g., voltage drift or noise on a power bus coupled to power a data receiver of the DRAM and coupled to power a clock receiver of the DRAM). Voltage drift (e.g., voltage fluctuations) on the power bus may cause jitter (e.g., a timing offset or a timing margin violation) at latches coupled to the data receiver and the clock receiver.

In conventional DRAM architectures with a relatively low frequency of operation, a one-time calibration event may reduce timing margin violations. For example, the one-time calibration event may include a “safeguard” for relatively small voltage drift on the power bus. However, as the frequency of operation increases and the timing margin decreases, voltage drift on the power bus may cause an increased amount of jitter between the data receiver and the clock receiver.

### III. SUMMARY

Systems, methods, and techniques are disclosed for reducing jitter at a dynamic random access memory (DRAM). A controller may provide data to a data receiver of a DRAM and may provide DRAM clock signals to a clock receiver of the DRAM. A power source may supply power to the controller and to the DRAM (e.g., to the data receiver and to the clock receiver). Using power received from the power source, the controller may send the data to the data receiver using a DRAM interface. However, sending a burst of data (e.g., a relatively large amount of data in a short time period) to the data receiver via a DRAM data bus after an idle period (e.g., a period of time when data is not sent via the DRAM data bus) may cause voltage fluctuations (e.g., noise) on the power bus. The voltage fluctuations on the power bus may cause timing skew (e.g., jitter or a timing violation) between the data receiver and the clock receiver. For example, sending a burst of data to the data receiver may require that the power source provide an increased amount of power to the controller during a short period of time, which may cause voltage fluctuations on the power bus.

To reduce voltage fluctuations at the power bus, a traffic shaper and a timing adjuster within the controller may apply a smoothing function (e.g., traffic shaping) to the data on the DRAM data bus to spread out the data traffic (e.g., reduce the data rate of the data traffic) when there is a relatively large rate-of-change in the volume of data traffic. Spreading out the data traffic may reduce the amount of voltage drift (e.g., the amount of voltage fluctuations) on the power bus. The traffic shaper may be calibrated to determine a relationship between a change in data rate on the DRAM data bus and a magnitude of voltage fluctuation at the power bus. After calibration, the timing adjuster may work in conjunction with the traffic shaper to adjust the rate of data traffic on the DRAM data bus (if the rate-of-change of data traffic of the DRAM data bus satisfies a threshold) to reduce the amount of voltage fluctuations at the power bus. Reducing the amount of voltage fluctuations at the power bus may decrease the amount of jitter between the data receiver and the clock receiver.

In a particular aspect, a method includes detecting, at a controller, a rate-of-change between first data traffic to be sent to a dynamic random access memory (DRAM) at a first time and second data traffic to be sent to the DRAM at a second time. The method includes adjusting a data rate of the second data traffic in response to a determination that the rate-of-change satisfies a threshold.

In another particular aspect, an apparatus includes a processor and a memory. The memory includes instructions that are executable by the processor to perform operations. The operations include detecting a rate-of-change between first data traffic to be sent to a dynamic random access memory (DRAM) at a first time and second data traffic to be sent to the DRAM at a second time. The operations also include adjusting a data rate of the second data traffic in response to a determination that the rate-of-change satisfies a threshold.

In another particular aspect, a non-transitory computer-readable medium includes instructions that, when executed by a processor, cause the processor to detect a rate-of-change between first data traffic to be sent to a dynamic random access memory (DRAM) at a first time and second data traffic to be sent to the DRAM at a second time. The instructions are also executable to cause the processor to adjust a data rate of the second data traffic in response to a determination that the rate-of-change satisfies a threshold.

In another particular aspect, an apparatus includes means for detecting a rate-of-change between first data traffic to be sent to a dynamic random access memory (DRAM) at a first time and second data traffic to be sent to the DRAM at a second time. The apparatus also includes means for adjusting a data rate of the second data traffic in response to a determination that the rate-of-change satisfies a threshold.

In another particular aspect, a method includes detecting, at a controller, a rate-of-change between first data traffic to be read from a dynamic random access memory (DRAM) at a first time and second data traffic to be read from the DRAM at a second time. The method includes adjusting a data rate of the second data traffic in response to a determination that the rate-of-change satisfies a threshold.

In another particular aspect, an apparatus includes a processor and a memory. The memory includes instructions that are executable by the processor to perform operations. The operations include detecting a rate-of-change between first data traffic to be read from a dynamic random access memory (DRAM) at a first time and second data traffic to read from the DRAM at a second time. The operations also include adjusting a data rate of the second data traffic in response to a determination that the rate-of-change satisfies a threshold.

In another particular aspect, a non-transitory computer-readable medium includes instructions that, when executed by a processor, cause the processor to detect a rate-of-change between first data traffic to be read from a dynamic random access memory (DRAM) at a first time and second data traffic to be read from the DRAM at a second time. The instructions are also executable to cause the processor to adjust a data rate of the second data traffic in response to a determination that the rate-of-change satisfies a threshold.

In another particular aspect, an apparatus includes means for detecting a rate-of-change between first data traffic to be read from a dynamic random access memory (DRAM) at a first time and second data traffic to be read from the DRAM at a second time. The apparatus also includes means for adjusting a data rate of the second data traffic in response to a determination that the rate-of-change satisfies a threshold.

One particular advantage provided by at least one of the disclosed aspects is an ability to reduce an amount of jitter between a data receiver of a dynamic random access memory (DRAM) and a clock receiver of the DRAM. For example, a data rate of data traffic sent to the data receiver may be reduced to decrease noise (e.g., voltage fluctuations) at a power bus coupled to the data receiver and to the clock receiver. Decreasing the noise may reduce the amount of jitter between the data receiver and the clock receiver. Other aspects, advantages, and features of the present disclosure will become apparent after review of the entire application, including the following sections: Brief Description of the Drawings, Detailed Description, and the Claims.

### IV. BRIEF DESCRIPTION OF THE DRAWINGS

FIG. 1 is a diagram of a particular illustrative aspect of a system that is operable to reduce jitter-based errors at a dynamic random access memory (DRAM);

FIG. 2 includes diagrams of particular aspects illustrating voltage fluctuation on a power bus according to data traffic sent on a DRAM data bus;

FIG. 3 is a diagram of a traffic shaping rule table;

FIG. 4 is a flowchart of a particular aspect of a method for selecting a traffic shaping rule to reduce jitter at a DRAM;

FIG. 5 is a flowchart of a particular aspect of a method for populating a traffic shaping rule table;

FIG. 6 is a flowchart of a particular aspect of a method for reducing jitter-based errors at a DRAM;

FIG. 7 is a flowchart of another particular aspect of a method for reducing jitter-based errors at a DRAM;

FIG. 8 is a diagram of another particular illustrative aspect of a system that is operable to reduce jitter-based errors at a DRAM;

FIG. 9 is a block diagram of a wireless device including components that are operable to reduce jitter-based errors at a DRAM; and

FIG. 10 is a data flow diagram of a particular illustrative aspect of a manufacturing process to manufacture electronic devices that include components that are operable to reduce jitter-based errors at a DRAM.

### V. DETAILED DESCRIPTION

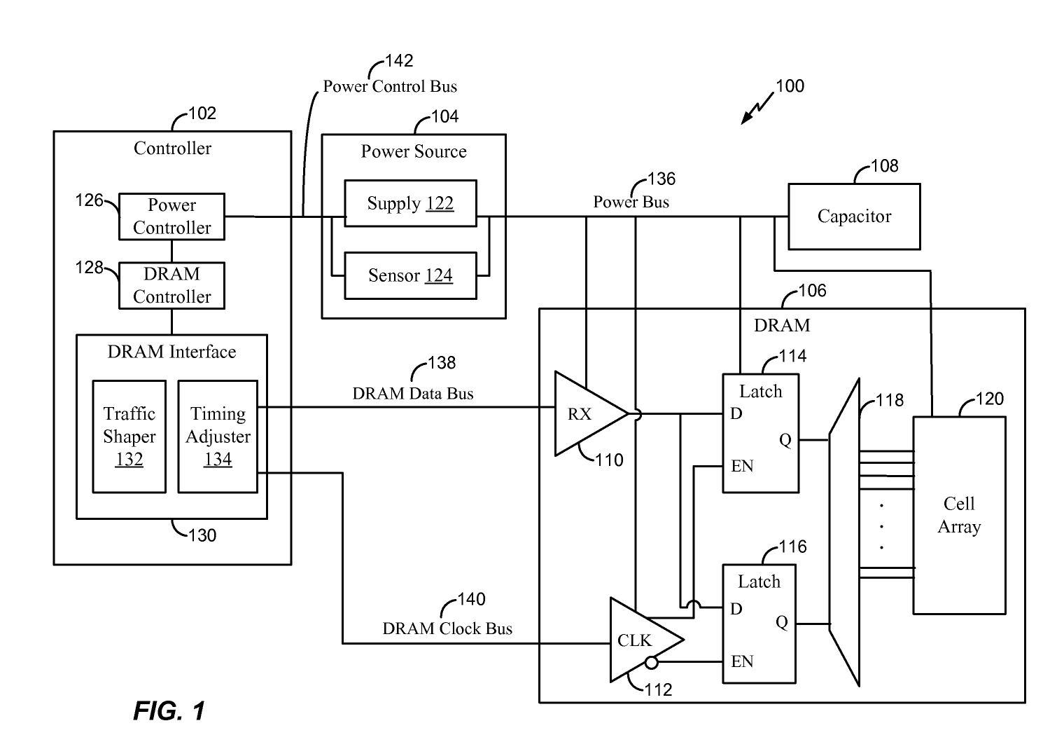

Referring to FIG. 1, a particular illustrative aspect of a system 100 that is operable to reduce jitter-based errors at a dynamic random access memory (DRAM) is shown. The system 100 includes a controller 102, a power source 104, a DRAM 106, and a capacitor 108.

The DRAM 106 includes a data receiver (RX) 110 and a clock receiver (CLK) 112. The data receiver 110 and the clock receiver 112 may be coupled to receive power from a power bus 136. The DRAM 106 also includes a first latch 114 (e.g., a first D-type flip-flop circuit) and a second latch 116 (e.g., a second D-type flip-flop circuit). For example, an output of the data receiver 110 may be coupled to a data input (D) of the first latch 114 and to a data input (D) of the second latch 116. An output of the clock receiver 112 may be coupled to an enable input (EN) of the first latch 114, and an inverted output of the clock receiver 112 may be coupled to an enable input (EN) of the second latch 116. For example, the clock receiver 112 may be configured to provide a clock signal to the first latch 114 and an inverted clock signal to the second latch 116.

Each latch 114, 116 may be configured to store data and to provide the stored data to a cell array 120 (e.g., a DRAM cell array) via a switching circuit, such as a demultiplexer 118, according to a D-type flip-flop operation. For example, when the clock signal from the clock receiver 112 has a logical high voltage level (and the inverted clock signal has a logical low voltage level), the first latch 114 may output data at a data output (Q) of a current state (e.g., may pass-through the current data provided to the data input (D) of the first latch 114) and the second latch 116 may output data at a data output (Q) of a previous state (e.g., latched data). When the clock signal from the clock receiver 112 has a logical low voltage level (and the inverted clock signal has a logical high voltage level), the first latch 114 may output latched data of a previous state and the second latch 116 may output data of a current state (e.g., may pass-through the current data provided to the data input (D) of the second latch 116). Data output from the latches 114, 116 may be provided to the demultiplexer 118, and the demultiplexer 118 may be used to reduce the data rate of the outputs of the latches 114, 116 to match the lower operational frequency of the cell array 120 based on a selection signal (not shown).

The controller 102 (e.g., including a DRAM controller 128) may be configured to provide data to the DRAM 106 via a DRAM data bus 138, and the controller 102 may be configured to provide clock signals to the DRAM 106 via a DRAM clock bus 140. For example, the controller 102 may send data to the data receiver 110 via the DRAM data bus 138 using a DRAM interface 130, and the controller 102 may send clock signals to the clock receiver 112 via the DRAM clock bus 140 using the DRAM interface 130.

However, sending a burst of data (e.g., a relatively large amount of data in a short time period) via the DRAM data bus 138 after an idle period (e.g., a period of time where data is not sent via the DRAM data bus 138) may cause voltage fluctuations (e.g., noise) on the power bus 136 as the burst of toggling data energizes various elements within the DRAM 106 (including the data receiver 110, the data latches 114, 116, the demuliplexer 118, the cell array 120, and the circuit interconnect connecting these elements together). For example, the amount of data sent on the DRAM data bus 138 may cause the DRAM 106 to consume power provided by a power supply 122 within the power source 104. The capacitor 108 (coupled to the power bus 136) and the power supply 122 may not be able to “instantaneously respond” (e.g., immediately stabilize) to a voltage drop on the power bus 136 due to the data burst, which in turn may cause voltage fluctuations or “ringing” on the power bus 136.

The voltage fluctuations on power bus 136 may cause a skew (e.g., jitter or a timing violation) between the data receiver 110 and the clock receiver 112, which may result in the latches 114, 116 receiving data with errors. To illustrate, sending a burst of data to the data receiver 110 may require that the power supply 122 provide an increased amount of power to the controller 102 (e.g., to a power controller 126 within the controller 102) via a power control bus 142 during a short period of time to drive the DRAM interface 130. Providing the increased amount of power to the controller 102 may cause the voltage fluctuations at the power bus 136.

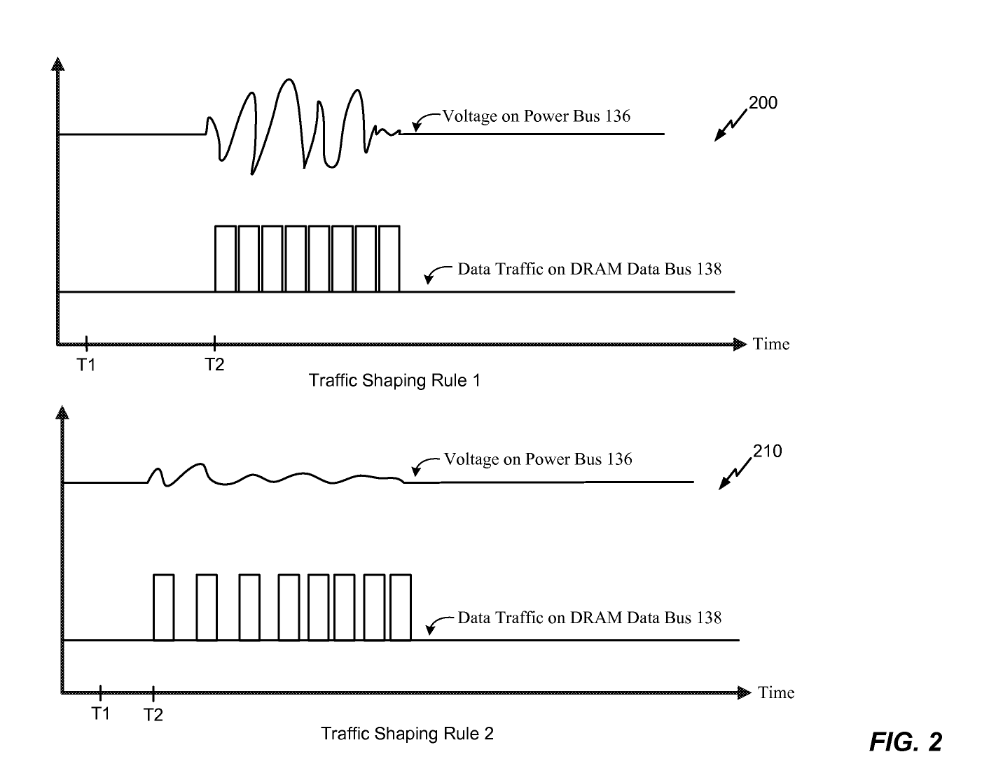

To reduce voltage fluctuations at the power bus 136, a traffic shaper 132 and a timing adjuster 134 may apply a smoothing function (e.g., traffic shaping) to data to be transferred on the DRAM data bus 138 to spread out data traffic (e.g., reduce the data rate of the data traffic) when there is a relatively large rate-of-change in the volume of traffic on the DRAM data bus 138. For example, the controller 102 may detect a rate-of-change between first data traffic to be sent to the DRAM 106 (e.g., the data receiver 110) at a first time and second data traffic to be sent to the DRAM 106 at a second time. Illustrations of data traffic to be sent on the DRAM data bus 138 at the first time and the second time are depicted with respect to FIG. 2. In response to a determination that the rate-of-change satisfies a threshold, the timing adjuster 134 may adjust a data rate of the second data traffic based on a rule associated with the rate-of-change. For example, the timing adjuster 134 may “spread out” (e.g., decrease the data rate of) the second data traffic to reduce the amount of noise on the power bus 136, thus reducing the amount of jitter between the data receiver 110 and the clock receiver 112. In addition, the timing adjuster 134 may include programmable delays for individual data bits which may be configured to remove static timing skews such as those created by unequal circuit trace lengths.

The traffic shaper 132 may operate in conjunction with the timing adjuster 134 to apply a rule to data to be sent to the data receiver 110 via the DRAM data bus 138. The rule may determine the data rate at which the data is sent to the data receiver 110. For example, the rule may determine whether data is to be “spread out” (e.g., sent at a lower data rate) to reduce voltage fluctuation on the power bus 136 and to reduce jitter between the data receiver 110 and the clock receiver 112. One or more such rules may be based on a size of the data (e.g., a “transaction size”) to be sent on the DRAM data bus 138 and based on an idle time on the DRAM data bus 138 prior to sending the data. In a particular aspect, a traffic shaping rule table may be populated at the traffic shaper 132, and the timing adjuster 134 may spread out the data (e.g., adjust the data rate of the data) to be sent on the DRAM data bus 138 based on the traffic shaping rule table.

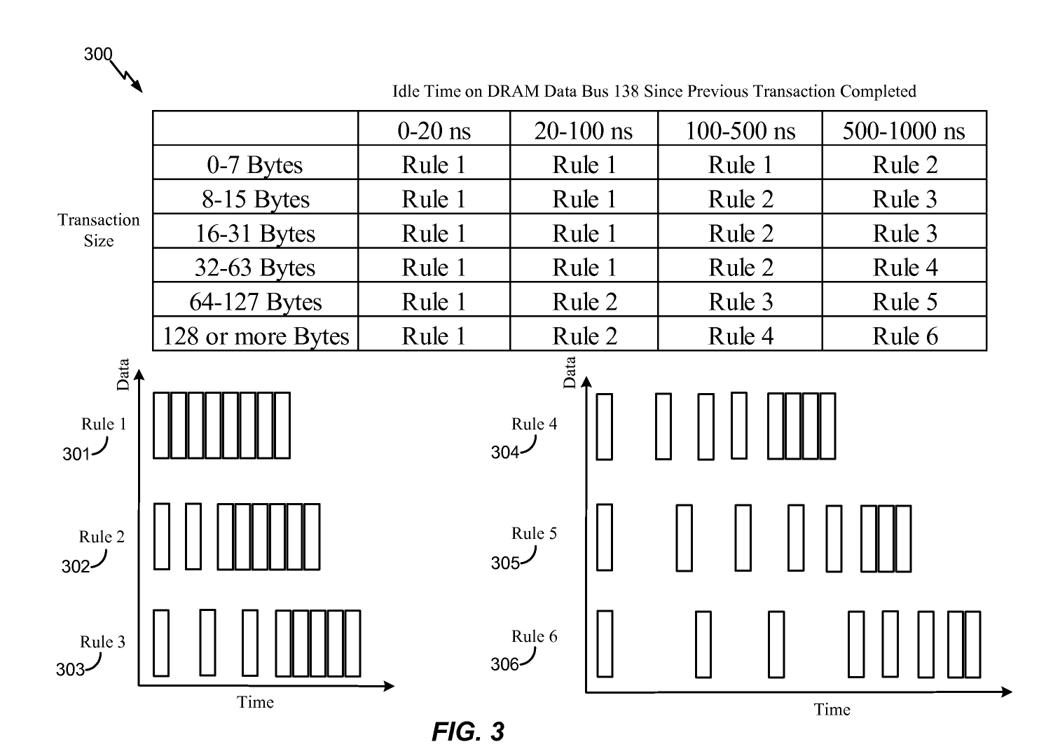

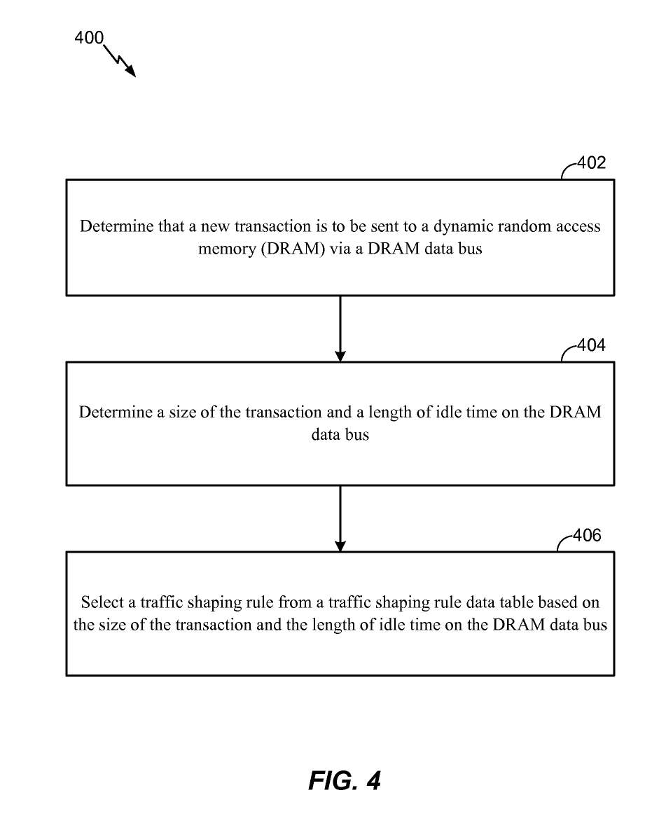

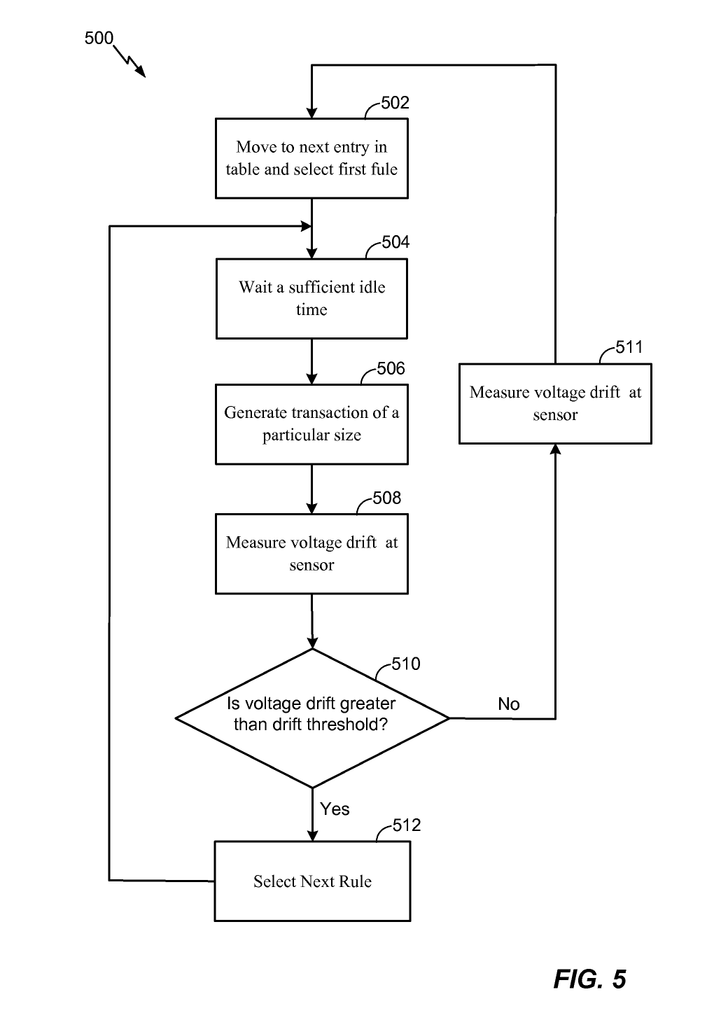

The traffic shaping rule table is described in further detail with respect to FIGS. 3-4. A sensor 124 within the power source 104 may be configured to measure voltage drift (e.g., the voltage fluctuation) on the power bus 136 to populate the traffic shaping rule table. For example, techniques to populate the traffic shaping rule table are described in further detail with respect to FIG. 5.

The system 100 of FIG. 1 may reduce an amount of jitter between the data receiver 110 of the DRAM 106 and the clock receiver 112 of the DRAM 106. For example, a data rate of data traffic sent to the data receiver 110 may be reduced according to one or more rules to decrease noise (e.g., voltage fluctuations) at the power bus 136. Decreasing the noise may reduce the amount of jitter between the data receiver 110 and the clock receiver 112.

Referring to FIG. 2, particular illustrations 200, 210 of voltage fluctuation on the power bus 136 according to data traffic sent on the DRAM data bus 138 are shown. The first illustration 200 depicts voltage fluctuation on the power bus 136 according to a first traffic shaping rule (as explained below), and the second illustration 210 depicts voltage fluctuation on the power bus 136 according to a second traffic shaping rule (as explained below). According to the illustrations 200, 210, the DRAM data bus 138 is idle at the first time (T1). For example, the controller 102 does not send any data to the data receiver 110 at the first time (T1).

With reference to the first illustration 200 (e.g., the first traffic shaping rule), sixty-four bytes of data may be sent to the data receiver 110 via the DRAM data bus 138 beginning at the second time (T2). For example, each block of data depicted in FIG. 2 may represent eight bytes of data that is driven on the data bus 138 to be sent to the data receiver 110. For example, the first traffic shaping rule may correspond to sending the data traffic to the data receiver 110 at a relatively high data rate). Sending the sixty-four bytes of data according to the first traffic shaping rule after an idle period may yield relatively large voltage fluctuations (e.g., relatively large amounts of noise) on the power bus 136.

With reference to the second illustration 210 (e.g., the second traffic shaping rule), sixty-four bytes of data may also be sent to the data receiver 110 via the DRAM data bus 138 beginning at the second time (T2). Sending the sixty-four bytes of data according to the second traffic shaping rule after an idle period may yield smaller voltage fluctuations on the power bus 136. For example, the second traffic shaping rule may correspond to initially sending the data traffic at a low rate and gradually increasing the rate at which data is sent to the data receiver 110 (e.g., spreading out the data traffic). Compared to the first traffic shaping rule, although it may take longer to send the sixty-four bytes of data according to second traffic shaping rule, the amount of noise on the power bus 136 is reduced, which may reduce jitter between the data receiver 110 and the clock receiver 112.

Referring to FIG. 3, a particular example of a populated traffic shaping rule table 300 that may be implemented at the traffic shaper 132 is shown. Each row of the traffic shaping rule table 300 may correspond to a different transaction size (e.g., a different amount of data to be sent on the DRAM data bus 138), and each column of the traffic shaping rule table 300 may correspond to an idle time on the DRAM data bus 138 since a previous transaction has been completed (e.g., a length of time that the DRAM data bus 138 has been idle).

Each rule in the traffic shaping rule table 300 may correspond to a different data rate at which data is sent on the DRAM data bus 138. For example, a first rule 301 (“Rule 1”) may correspond to a first data rate, a second rule 302 (“Rule 2”) may correspond to a second data rate, a third rule 303 (“Rule 3”) may correspond to a third data rate, a fourth rule 304 (“Rule 4”) may correspond to a fourth data rate, a fifth rule 305 (“Rule 5”) may correspond to a fifth data rate, and a sixth rule 306 (“Rule 6”) may correspond to a sixth data rate. If data is sent according to the first rule 301, the data may be sent at a relatively high data rate (e.g., the data may be sent over a relatively short time period). Sending the data at a relatively high data rate may enable higher throughput; however, sending the data at a relatively high data rate may use a relatively large amount of power over a relatively short time that can result in a relatively large amount of voltage fluctuation (e.g., noise) on the power bus 136, as described above.

The traffic shaping rule table 300 includes six rules ordered from Rule 1 to Rule 6. As the order of the rule increases, the rate at which data is sent on the DRAM data bus 138 decreases. For example, if data is sent according to the sixth rule 306, the data may be sent at a relatively low data rate (e.g., the data may be sent over a relatively long time period). Sending the data at a relatively low data rate may temporarily reduce the data throughput when data is re-started after a long idle period; however, starting the data at a relatively low data rate may also yield a relatively small amount of voltage fluctuation on the power bus 136. As used herein, sending data at a low data rate may correspond to initially sending the data at a low data rate and gradually increasing the data rate as more data is sent.

The selected traffic shaping rule may depend on the size of the transaction to be sent on the DRAM data bus 138 and may depend on the idle time on the DRAM data bus 138. For example, if the controller 102 determines that a size of the data (e.g., the transaction) to be sent on the DRAM data bus 138 is between eight and fifteen bytes and that there has been between 20 nanoseconds (ns) and 100 ns of idle time on the DRAM data bus 138, the timing adjuster 134 may apply the first traffic shaping rule 301 to the data. As another example, if the traffic shaper 132 determines that a size of the data to be sent on the DRAM data bus 138 is over 128 bytes and the that there has been between 500 ns and 1000 ns of idle time on the DRAM data bus 138, the timing adjuster 134 may apply the sixth traffic shaping rule 306 to the data.

The traffic shaping rule table 300 of FIG. 3 may enable the controller 102 to select a rule to adjust the rate at which data is sent on the DRAM data bus 138. For example, the controller 102 may select a rule based on conditions (e.g., transaction size and idle time) to send data to the DRAM 106 at a rate that reduces the amount of voltage fluctuations at the power bus 136 based on the conditions. Reducing the amount of voltage fluctuations on the power bus 136 may decrease the amount of timing margin violations (e.g., jitter) between the data receiver 110 and the clock receiver 112, reducing the amount of jitter-based errors.

Although the rules in the traffic shaping rule table 300 correspond to different data rates at which data is sent to the DRAM 106 via the DRAM data bus 138, in other aspects, each rule may correspond to sizes of data transmitted at each clock cycle. As a non-limiting example, the sixth rule 306 may correspond to sending data having relatively small size (e.g., 2 bytes) at a first clock cycle, sending data having a larger size (e.g., 4 bytes) at a second clock cycle, sending data having an even larger size (e.g., 8 bytes) at a third clock cycle, etc. The first rule 301 may correspond to sending data having the same size (e.g., 8 bytes) at each clock cycle. Thus, the higher the order of the rule, the more gradually the size of each data block transmitted on the DRAM data bus 138 is increased. Gradually increasing the size of each data block transmitted on the DRAM data bus 138 may also reduce noise on the power bus 136, which in turn may reduce jitter at the DRAM 106.

Referring to FIG. 4, a flowchart that illustrates a method 400 of selecting a traffic shaping rule is shown. The traffic shaping rule may be selected to reduce jitter at a DRAM. The method 400 may be performed by the controller 102 of FIG. 1.

The method 400 may include determining that a transaction is to be sent to a DRAM via a DRAM data bus, at 402. For example, referring to FIG. 1, the DRAM controller 128 may determine that a transaction (e.g., data) is to be sent to the data receiver 110 of the DRAM 106 via the DRAM data bus 138.

A size of the transaction and a length of idle time on the DRAM data bus may be determined, at 404. For example, referring to FIG. 1, the DRAM controller 128 may determine a size of the transaction and a length of idle time on the DRAM data bus 138 (e.g., a length of time or number of clock cycles since a previous transaction has been completed).

A traffic shaping rule may be selected from a traffic shaping rule table based on the size of the transaction and the length of idle time on the DRAM data bus, at 406. For example, referring to FIG. 1, the timing adjuster 134 may select a traffic shaping rule based on the size of the transaction and the length of idle time on the DRAM data 138. To illustrate, if the traffic shaper 132 determines that the data (e.g., the transaction) to be sent on the DRAM data bus 138 is between eight and fifteen bytes and that there has been between 20 ns and 100 ns of idle time on the DRAM data bus 138, the timing adjuster 134 may apply the first traffic shaping rule to the data based on the traffic shaping rule table 300. Alternatively, if the traffic shaper 132 determines that the data to be sent on the DRAM data bus 138 is over 128 bytes and the that there has been between 100 ns and 500 ns of idle time on the DRAM data bus 138, the timing adjuster 134 may apply the fourth traffic shaping rule to the data based on the traffic shaping rule table 300.

The method 400 of FIG. 4 may enable the controller 102 to select a rule to adjust the rate at which data is sent on the DRAM data bus 138. For example, the method 400 may enable the controller 102 to send data to the DRAM 106 at a rate that reduces the amount of voltage fluctuations at the power bus 136. Reducing the amount of voltage fluctuations on the power bus 136 may decrease timing margin violations (e.g., jitter) between the data receiver 110 and the clock receiver 112, reducing the amount of jitter-based errors.

Referring to FIG. 5, a flowchart that illustrates a method 500 for populating the traffic shaping rule table 300 is shown. The method 500 may be performed by the controller 102 of FIG. 1 and the sensor 124 of FIG. 1. For example, the method 500 may be used during an initialization or calibration process to test voltage fluctuations using the sensor 124 for various data transmission conditions. It should be clear that there may be significant variability in various wireless device 700 implementations, including the capacitance value of capacitor 108, the transient response behavior of power source 104, the circuit impedance of the power bus 136, or numerous other factors which vary from one design to another. The method 500 is intended to apply stimulus to the finished system, measure the response, and then use this to create a set of applied rules that will minimize voltage drift. As a result, timing margin improves and as a consequence either the system performance may be increased by raising the operating frequency or the cost may be reduced by substituting less expensive components (e.g. smaller capacitors or inductors, less complex power sources or printed circuit boards).

A first entry of the traffic shaping rule table 300 may be selected and a rule may be set (e.g., the rule may be initialized to the first traffic shaping rule), at 502. For example, the DRAM controller 128 may select to populate the entry of the traffic shaping rule table 300 corresponding to a transaction size between 0-7 bytes having an idle time between 0-20 ns. The DRAM controller 128 may wait a “sufficient” time (e.g., between 0-20 ns), at 504, and generate a transaction of a particular size (e.g., transmit a test pattern containing between 0-7 bytes), at 506. The time and size may be selected to be at edges of ranges (e.g., 20 ns and 7 bytes) to provide a highest voltage fluctuation condition for the first entry.

The controller 102 may send the transaction to the data receiver 110, and the sensor 124 may measure the voltage drift (e.g., a peak voltage drift or a minimum voltage drift) at the power bus 136, at 508. At 510, the controller 102 may determine whether the voltage drift is greater than a drift threshold. If the voltage drift is not greater than the drift threshold, the controller 102 may populate the first entry of the traffic shaping rule table 300 with the first traffic shaping rule, at 511. The controller 102 may then move to the next entry in the traffic shaping rule table 300 and reset the rule, at 502. If the voltage drift is greater than the drift threshold, the controller 102 may select another rule, such as by incrementing a rule number from the first traffic shaping rule to the second traffic shaping rule, and repeat acts 504-510 for the second traffic shaping rule. The method 500 may additionally be iterated using multiple unique test patterns. Determination of the traffic shaping rules may be based on the pattern which caused the worst voltage drift.

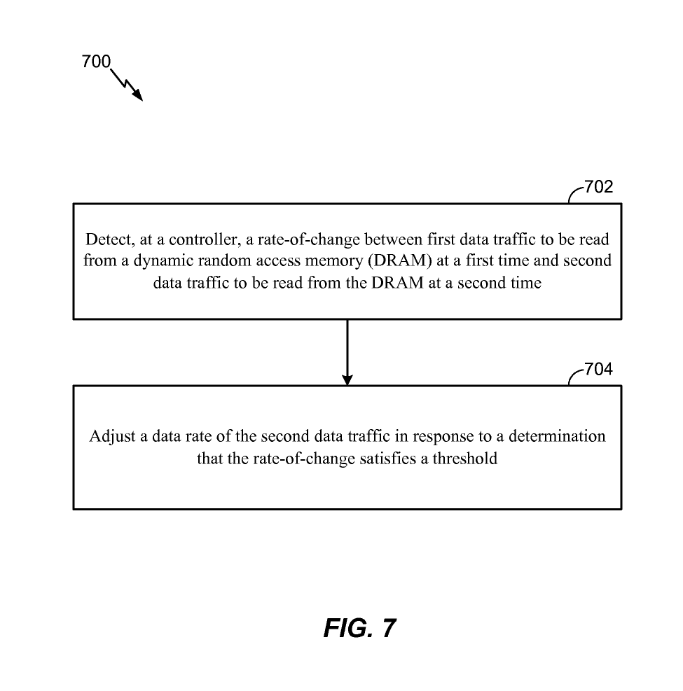

The method 500 of FIG. 5 may enable the controller 102 to populate the traffic shaping rule table 300. Additionally, the method 500 of FIG. 5 may enable the controller 102 to repopulate (e.g., recalibrate) the rules in the traffic shaping rule table 300 over time to adjust for process, voltage, and temperature (PVT) variations that may change the amount of voltage drift on power bus 136 for a given condition (e.g., transaction size and idle time). In a particular aspect, calibration may occur during initialization and may be repeated during normal operation. Calibration (and recalibration) may be performed using operating system software executed on a central processing unit (CPU), a digital signal processor (DSP) (as described with respect to FIG. 7), or dedicated hardware. Calibration may determine the relationship between data traffic transients on the DRAM data bus 138 and voltage transients on the power bus 136.

Recalibrating the rules in the traffic shaping rule table 300 may enable the controller 102 to select a “calibrated rule” at a given PVT conditions to adjust the rate at which data is sent on the DRAM data bus 138. By selecting a calibrated rule, the controller 102 may send data to the DRAM 106 at a rate that reduces the amount of voltage fluctuations at the power bus 136. Reducing the amount of voltage fluctuations on the power bus 136 may decrease the amount of timing margin violations (e.g., jitter) between the data receiver 110 and the clock receiver 112, which in turn, may reduce the amount of jitter-based errors.

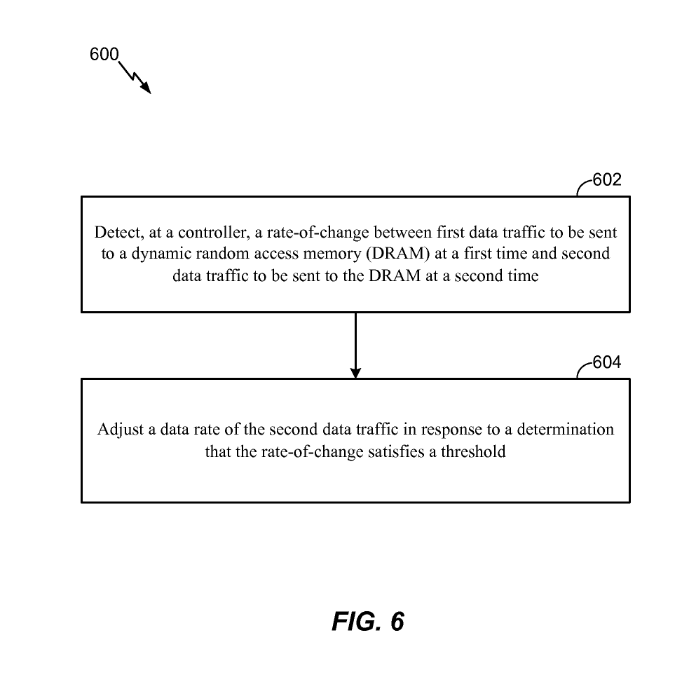

Referring to FIG. 6, a flowchart that illustrates a method 600 of selecting a data rate is shown. The method 600 may be used to reduce jitter-based errors at a DRAM. The method 600 may be performed using the system 100 of FIG. 1.

The method 600 includes detecting, at a controller, a rate-of-change between first data traffic to be sent to a DRAM at a first time and second data traffic to be sent to the DRAM at a second time, at 602. For example, referring to FIG. 1, the controller 102 may detect a rate-of-change between first data traffic to be sent to the DRAM 106 (e.g., the data receiver 110) at a first time and second data traffic to be sent to the DRAM 106 at a second time.

A data rate of the second data traffic may be adjusted in response to a determination that the rate-of-change satisfies a threshold, at 604. For example, referring to FIG. 1, a traffic shaper 132 and a timing adjuster 134 may apply a smoothing function (e.g., traffic shaping) to the data on the DRAM data bus 138 to spread out data traffic (e.g., reduce the data rate of the data traffic) when there is a relatively large rate-of-change in the volume of traffic on the DRAM data bus 138. In response to a determination that the rate-of-change satisfies a threshold, the timing adjuster 134 may adjust a data rate of the second data traffic based on a rule associated with the rate-of-change. For example, the timing adjuster 134 may “spread out” (e.g., decrease the data rate of) the second data traffic based on the rules in the traffic shaping rule table 300 to reduce the amount of noise on the power bus (thus reducing the amount of jitter between the data receiver 110 and the clock receiver 112).

Adjusting a data rate based on the method 600 of FIG. 6 may reduce an amount of jitter between the data receiver 110 of the DRAM 106 and the clock receiver 112 of the DRAM 106. For example, a data rate of data traffic sent to the data receiver 110 may be reduced according to rules to decrease noise (e.g., voltage fluctuations) at the power bus 136. Decreasing the noise may reduce the amount of jitter between the data receiver 110 and the clock receiver 112.

The foregoing descriptions involve traffic shaping when writing data to the DRAM which typically is more problematic to manage receiver timing jitter induced by voltage drift arising from large current spikes created within the DRAM 106 as it is written. However, in another embodiment, when reading data from the DRAM, similar methods can also be applied in a reverse direction.

For example, referring to FIG. 7, a method 700 of adjusting a read data rate to reduce an amount of jitter between a data transmitter and a clock transmitter inside a DRAM is shown. For example, a data rate of data traffic read from the DRAM 106 may be reduced according to rules to decrease noise (e.g., voltage fluctuations) at the power bus. Decreasing the noise may reduce the amount of jitter between the data transmitter and the clock transmitter within the DRAM. During the read, data is sent from the DRAM to receivers within the controller. The reduced jitter improves the timing margin at the controller as the controller receives the data. Typically, the DRAM data bus is bidirectional and may be used for either writing or reading. In one embodiment, the method 600 of FIG. 6 may be applied during write operations and the method 700 of FIG. 7 may be applied during read operations.

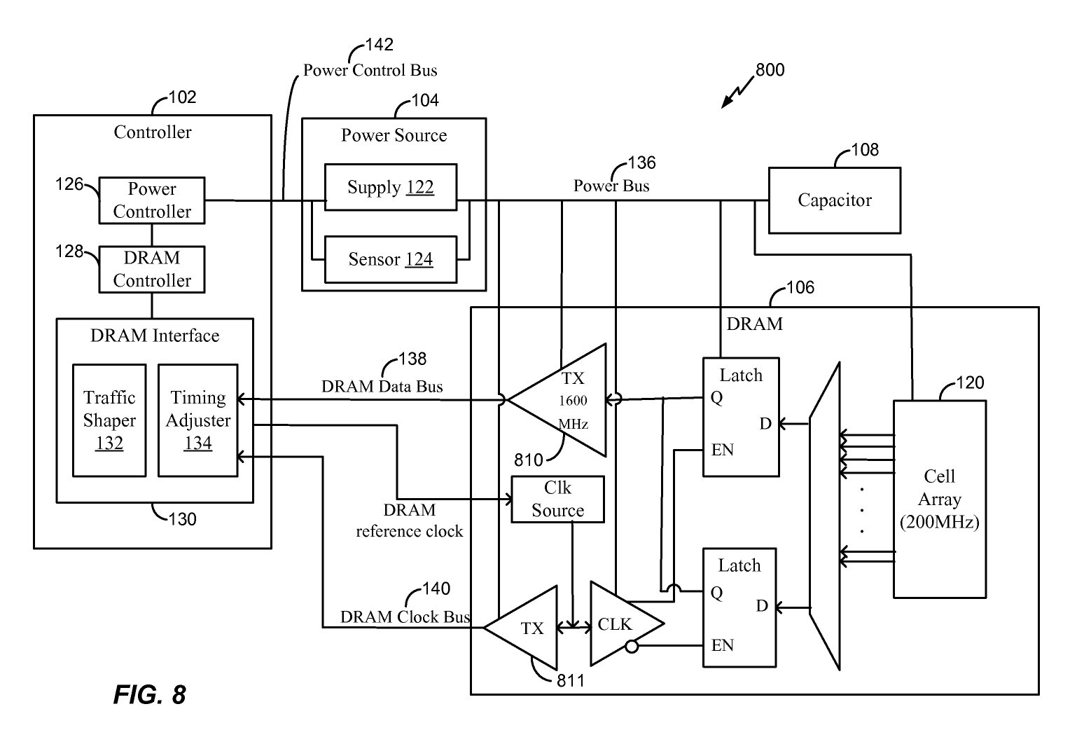

The method 700 is described with respect to the system 800 of FIG. 8. The method 700 includes detecting, at a controller, a rate-of-change between first read data traffic requested from the DRAM at a first time and second data traffic expected to be requested from the DRAM at a second time, at 702. For example, referring to FIG. 8, the controller 102 may detect a rate-of-change between first data traffic read from a DRAM 106 (e.g., from a data transmitter 810) at a first time and second data traffic expected to be read from the DRAM 106 at a second time.

A data rate of the second data traffic may be adjusted in response to a determination that the rate-of-change satisfies a threshold, at 704. For example, referring to FIG. 8, the traffic shaper 132 and the timing adjuster 134 may apply a smoothing function (e.g., traffic shaping) to request the data from the DRAM 806 such that the requests spread out data traffic (e.g., reduce the data rate of the data traffic) when there is a relatively large rate-of-change in the volume of traffic expected to be read from the DRAM 106 on the DRAM data bus 138. In response to a determination that the rate-of-change satisfies a threshold, the timing adjuster 134 may adjust a data rate of the second data traffic based on a rule associated with the rate-of-change. For example, the timing adjuster 134 may “spread out” (e.g., decrease the data rate of) the second data traffic based on the rules in the traffic shaping rule table 300 to reduce the amount of noise on the power bus 136 (thus reducing the amount of jitter between the data transmitter 810 and the clock transmitter 811). In a particular embodiment, the first data traffic may be a DRAM write and the second data traffic may be a DRAM read request. In another particular embodiment, the first data traffic may be a DRAM read and the second data traffic may be a DRAM write.

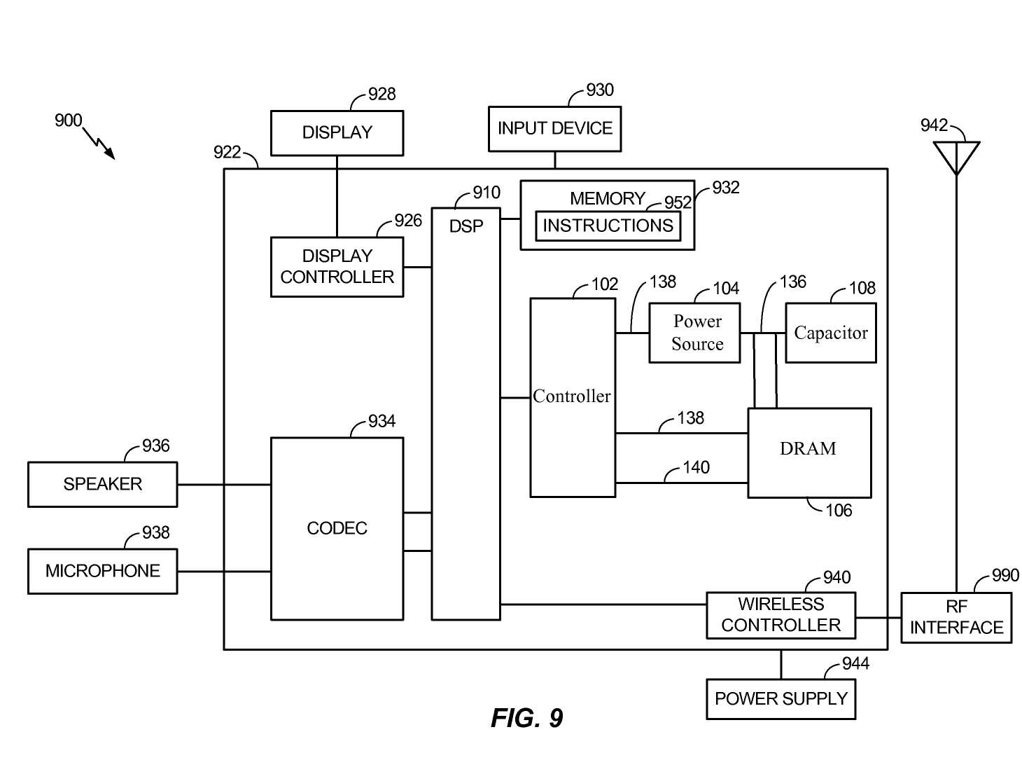

Referring to FIG. 9, a block diagram of a wireless device 900 including components that are operable to reduce jitter-based errors at a DRAM is shown. The wireless device 900 includes a processor 910, such as a digital signal processor (DSP), coupled to a memory 932. The wireless device 900 also includes the system 100 of

FIG. 1. For example, the wireless device 900 also includes the controller 102, the power source 104, the DRAM 106, and the capacitor 108.

The controller 102 may be coupled to the processor 910. The power control bus 142 of FIG. 1 may be coupled to the controller 102 and to the power source 104. The power bus 136 may be coupled to the power source 104, to the capacitor 108, and to the DRAM 106. The controller 102 may provide data to the DRAM 106 via the DRAM data bus 138, and the controller 102 may provide clock signal to the DRAM 106 via the DRAM clock bus 140. The controller 102, the power source 104, the DRAM 106, and the capacitor 108 may operate in a substantially similar manner as described with respect to one or more of FIGS. 1-6 to reduce noise on the power bus 136, and thus reduce jitter at the DRAM 106.

The memory 932 may be a non-transitory processor-readable storage medium that includes instructions 952. The instructions may be executable by the processor 910 and/or the controller 102 to perform one or more of the methods 400-600 of FIGS. 4-6. The wireless device 900 may also include a display controller 926 that is coupled to the processor 910 and to a display 928. A coder/decoder (CODEC) 934 can also be coupled to the processor 910. A speaker 936 and a microphone 938 can be coupled to the CODEC 934 and to the processor 910. FIG. 9 also indicates that a wireless controller 940 can be coupled to the processor 910. The wireless controller 940 may also be coupled to an antenna 942 via a radio frequency (RF) interface 990.

In a particular aspect, the processor 910, the display controller 926, the memory 932, the CODEC 934, and the wireless controller 940 are included in a system-in-package or system-on-chip device 922. In a particular aspect, an input device 930 and a power supply 944 are coupled to the system-on-chip device 922. Moreover, in a particular aspect, as illustrated in FIG. 9, the display 928, the input device 930, the speaker 936, the microphone 938, the antenna 942, and the power supply 944 are external to the system-on-chip device 922. However, each of the display 928, the input device 930, the speaker 936, the microphone 938, the antenna 942, and the power supply 944 can be coupled to a component of the system-on-chip device 922, such as an interface or a controller.

In conjunction with the described aspects, an apparatus includes means for detecting a rate-of-change between first data traffic to be sent to a DRAM at a first time and second data traffic to be sent to the DRAM at a second time. For example, the means for detecting may include the controller 102 of FIGS. 1, 8, and 9 and the components thereof, the instructions 952 executable by the processor 910 of FIG. 9, one or more other devices, circuits, modules, or any combination thereof. For example, the DRAM controller 128 may be programmed to store data indicating an amount of data to be transmitted over each of several time periods and may subtract a first amount from a second amount to determine the change in amount of data to be transmitted over the change in time.

The apparatus also includes means for adjusting a data rate of the second data traffic in response to a determination that the rate-of-change satisfies a threshold. For example, the means for adjusting the data rate may include the controller 102 of FIGS. 1 and 9 and the components thereof, the instructions 952 executable by the processor 910 of FIG. 9, one or more other devices, circuits, modules, or any combination thereof. For example, the DRAM controller 128 may be programmed to compare the change in amount of data to be transmitted over the change in time to a threshold. In response to the change in the amount of data to be transmitted over the change in time (e.g., the rate-of-change) exceeding the threshold, the DRAM controller 128 may perform a table lookup operation (e.g., a lookup of a corresponding rule in the traffic shaping rule table 300 of FIG. 3). For example, during the lookup operation, the DRAM controller 128 may retrieve a rule corresponding to the rate-of-change and may adjust the traffic shaper 132 and the timing adjuster 134 to apply the retrieved rule. In conjunction with reducing the data rate on DRAM data bus 138, the controller 102 may provide a feedback signal to the DSP 910 and other processors to prevent the occurrence of a data overflow.

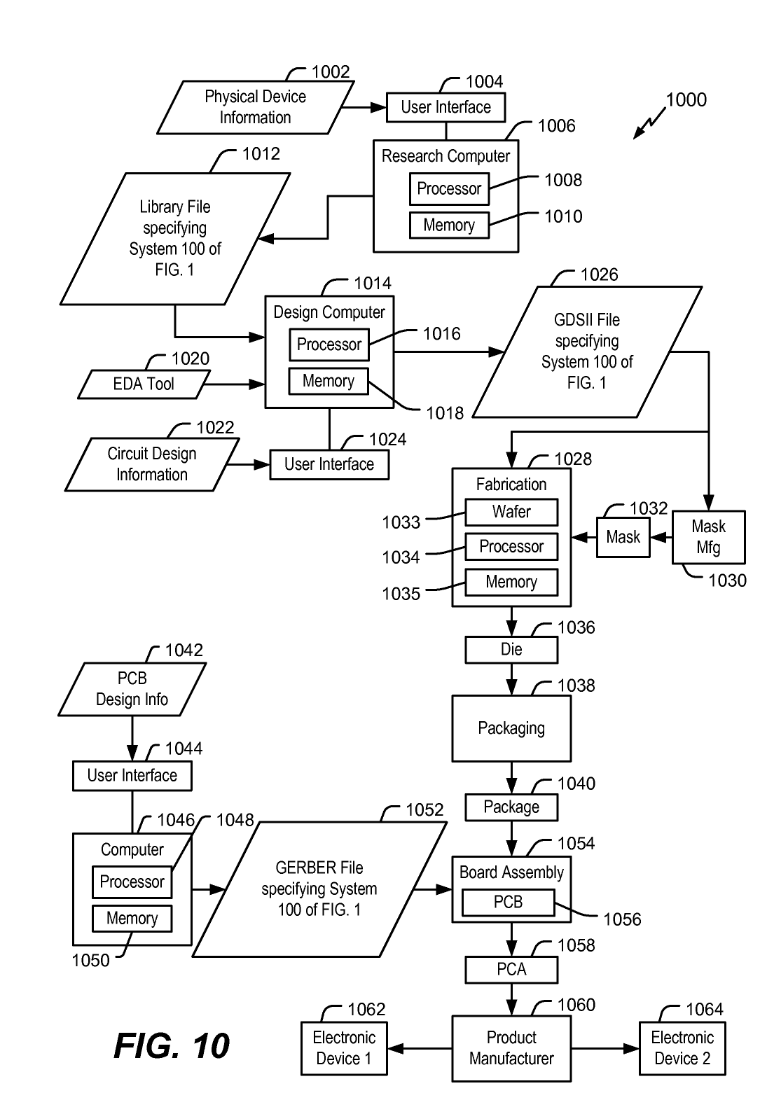

The foregoing disclosed devices and functionalities may be designed and configured into computer files (e.g., RTL, GDSII, GERBER, etc.) stored on computer-readable media. Some or all such files may be provided to fabrication handlers to fabricate devices based on such files. Resulting products include wafers that are then cut into dies and packaged into chips. The chips are then employed in devices described above. FIG. 10 depicts a particular illustrative embodiment of an electronic device manufacturing process 1000.

Physical device information 1002 is received at the manufacturing process 1000, such as at a research computer 1006. The physical device information 1002 may include design information representing at least one physical property of a semiconductor device, such as a physical property of a device that includes the system 100 of FIG. 1. For example, the physical device information 1002 may include physical parameters, material characteristics, and structure information that is entered via a user interface 1004 coupled to the research computer 1006. The research computer 1006 includes a processor 1008, such as one or more processing cores, coupled to a computer-readable medium such as a memory 1010. The memory 1010 may store computer-readable instructions that are executable to cause the processor 1008 to transform the physical device information 1002 to comply with a file format and to generate a library file 1012.

In a particular aspect, the library file 1012 includes at least one data file including the transformed design information. For example, the library file 1012 may include a library of semiconductor devices, including a device that includes the system 100 of FIG. 1, provided for use with an electronic design automation (EDA) tool 1020.

The library file 1012 may be used in conjunction with the EDA tool 1020 at a design computer 1014 including a processor 1016, such as one or more processing cores, coupled to a memory 1018. The EDA tool 1020 may be stored as processor executable instructions at the memory 1018 to enable a user of the design computer 1014 to design a circuit including a device that includes the system 100 of FIG. 1, using the library file 1012. For example, a user of the design computer 1014 may enter circuit design information 1022 via a user interface 1024 coupled to the design computer 1014. The circuit design information 1022 may include design information representing at least one physical property of a semiconductor device, such as a device that includes the system 100 of FIG. 1. To illustrate, the circuit design property may include identification of particular circuits and relationships to other elements in a circuit design, positioning information, feature size information, interconnection information, or other information representing a physical property of an electronic device.

The design computer 1014 may be configured to transform the design information, including the circuit design information 1022, to comply with a file format. To illustrate, the file formation may include a database binary file format representing planar geometric shapes, text labels, and other information about a circuit layout in a hierarchical format, such as a Graphic Data System (GDSII) file format. The design computer 1014 may be configured to generate a data file including the transformed design information, such as a GDSII file 1026 that includes information describing a device that includes the system 100 of FIG. 1, in addition to other circuits or information. To illustrate, the data file may include information corresponding to a system-on-chip (SOC) or a chip interposer component that that includes a device that includes the system 100 of FIG. 1, and that also includes additional electronic circuits and components within the SOC.

The GDSII file 1026 may be received at a fabrication process 1028 to manufacture a device that includes the system 100 of FIG. 1 according to transformed information in the GDSII file 1026. For example, a device manufacture process may include providing the GDSII file 1026 to a mask manufacturer 1030 to create one or more masks, such as masks to be used with photolithography processing, illustrated in FIG. 10 as a representative mask 1032. The mask 1032 may be used during the fabrication process to generate one or more wafers 1033, which may be tested and separated into dies, such as a representative die 1036. The die 1036 includes a circuit including a device that includes the system 100 of FIG. 1.

In a particular aspect, the fabrication process 1028 may be initiated by or controlled by a processor 1034. The processor 1034 may access a memory 1035 that includes executable instructions such as computer-readable instructions or processor-readable instructions. The executable instructions may include one or more instructions that are executable by a computer, such as the processor 1034.

The fabrication process 1028 may be implemented by a fabrication system that is fully automated or partially automated. For example, the fabrication process 1028 may be automated and may perform processing steps according to a schedule. The fabrication system may include fabrication equipment (e.g., processing tools) to perform one or more operations to form an electronic device. For example, the fabrication equipment may be configured to perform one or more of the processes described with reference to FIGS. 1-9 using integrated circuit manufacturing processes (e.g., wet etching, chemical vapor etching, dry etching, deposition, chemical vapor deposition, planarization, lithography, in-situ baking, or a combination thereof).

The fabrication system may have a distributed architecture (e.g., a hierarchy). For example, the fabrication system may include one or more processors, such as the processor 1034, one or more memories, such as the memory 1035, and/or controllers that are distributed according to the distributed architecture. The distributed architecture may include a high-level processor that controls or initiates operations of one or more low-level systems. For example, a high-level portion of the fabrication process 1028 may include one or more processors, such as the processor 1034, and the low-level systems may each include or may be controlled by one or more corresponding controllers. A particular controller of a particular low-level system may receive one or more instructions (e.g., commands) from a high-level system, may issue sub-commands to subordinate modules or process tools, and may communicate status data back to the high-level system. Each of the one or more low-level systems may be associated with one or more corresponding pieces of fabrication equipment (e.g., processing tools). In a particular aspect, the fabrication system may include multiple processors that are distributed in the fabrication system. For example, a controller of a low-level system component of the fabrication system may include a processor, such as the processor 1034.

Alternatively, the processor 1034 may be a part of a high-level system, subsystem, or component of the fabrication system. In another aspect, the processor 1034 includes distributed processing at various levels and components of a fabrication system.

The die 1036 may be provided to a packaging process 1038 where the die 1036 is incorporated into a representative package 1040. For example, the package 1040 may include the single die 1036 or multiple dies, such as a system-in-package (SiP) arrangement. The package 1040 may be configured to conform to one or more standards or specifications, such as Joint Electron Device Engineering Council (JEDEC) standards.

Information regarding the package 1040 may be distributed to various product designers, such as via a component library stored at a computer 1046. The computer 1046 may include a processor 1048, such as one or more processing cores, coupled to a memory 1050. A printed circuit board (PCB) tool may be stored as processor executable instructions at the memory 1050 to process PCB design information 1042 received from a user of the computer 1046 via a user interface 1044. The PCB design information 1042 may include physical positioning information of a packaged electronic device on a circuit board, the packaged electronic device corresponding to the package 1040 including a device that includes the system 100 of FIG. 1.

The computer 1046 may be configured to transform the PCB design information 1042 to generate a data file, such as a GERBER file 1052 with data that includes physical positioning information of a packaged electronic device on a circuit board, as well as layout of electrical connections such as traces and vias, where the packaged electronic device corresponds to the package 1040 including a device that includes the system 100 of FIG. 1. In other aspects, the data file generated by the transformed PCB design information may have a format other than a GERBER format.

The GERBER file 1052 may be received at a board assembly process 1054 and used to create PCBs, such as a representative PCB 1056, manufactured in accordance with the design information stored within the GERBER file 1052. For example, the GERBER file 1052 may be uploaded to one or more machines to perform various steps of a PCB production process. The PCB 1056 may be populated with electronic components including the package 1040 to form a representative printed circuit assembly (PCA) 1058.

The PCA 1058 may be received at a product manufacturer 1060 and integrated into one or more electronic devices, such as a first representative electronic device 1062 and a second representative electronic device 1064. As an illustrative, non-limiting example, the first representative electronic device 1062, the second representative electronic device 1064, or both, may be selected from a set top box, a music player, a video player, an entertainment unit, a navigation device, a communications device, a personal digital assistant (PDA), a fixed location data unit, and a computer, into which a device that includes the system 100 of FIG. 1, is integrated. As another illustrative, non-limiting example, one or more of the electronic devices 1062 and 1064 may be remote units such as mobile phones, hand-held personal communication systems (PCS) units, portable data units such as personal data assistants, global positioning system (GPS) enabled devices, navigation devices, fixed location data units such as meter reading equipment, or any other device that stores or retrieves data or computer instructions, or any combination thereof. Although FIG. 10 illustrates remote units according to teachings of the disclosure, the disclosure is not limited to these illustrated units. Aspects of the disclosure may be suitably employed in any device which includes active integrated circuitry including memory and on-chip circuitry.

A device that includes a device that includes the system 100 of FIG. 1, may be fabricated, processed, and incorporated into an electronic device, as described in the illustrative manufacturing process 1000. One or more of the aspects disclosed with respect to FIGS. 1-7 may be included at various processing stages, such as within the library file 1012, the GDSII file 1026, and the GERBER file 1052, as well as stored at the memory 1010 of the research computer 1006, the memory 1018 of the design computer 1014, the memory 1050 of the computer 1046, the memory of one or more other computers or processors (not shown) used at the various stages, such as at the board assembly process 1054, and also incorporated into one or more other physical aspects, such as the mask 1032, the die 1036, the package 1040, the PCA 1058, other products such as prototype circuits or devices (not shown), or any combination thereof. Although various representative stages are depicted with reference to FIGS. 1-7, in other aspects, fewer stages may be used or additional stages may be included. Similarly, the process 1000 of FIG. 10 may be performed by a single entity or by one or more entities performing various stages of the manufacturing process 1000.

Those of skill would further appreciate that the various illustrative logical blocks, configurations, modules, circuits, and algorithm steps described in connection with the aspects disclosed herein may be implemented as electronic hardware, computer software, or combinations of both. Various illustrative components, blocks, configurations, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The steps of a method or algorithm described in connection with the aspects disclosed herein may be embodied directly in hardware, in a software module executed by a processor, or in a combination of the two. A software module may reside in random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of storage medium known in the art. An exemplary non-transitory (e.g. tangible) storage medium is coupled to the processor such that the processor can read information from, and write information to, the storage medium. In the alternative, the storage medium may be integral to the processor. The processor and the storage medium may reside in an application-specific integrated circuit (ASIC). The ASIC may reside in a computing device or a user terminal In the alternative, the processor and the storage medium may reside as discrete components in a computing device or user terminal

The previous description of the disclosed aspects is provided to enable a person skilled in the art to make or use the disclosed aspects. Various modifications to these aspects will be readily apparent to those skilled in the art, and the principles defined herein may be applied to other aspects without departing from the scope of the disclosure. Thus, the present disclosure is not intended to be limited to the aspects shown herein but is to be accorded the widest scope possible consistent with the principles and novel features as defined by the following claims.

What is claimed is:

1. A method comprising:
detecting, at a controller, a rate-of-change between first data traffic to be sent to a dynamic random access memory (DRAM) at a first time and second data traffic to be sent to the DRAM at a second time; and
adjusting a data rate of the second data traffic in response to a determination that the rate-of-change satisfies a threshold.

2. The method of claim 1, wherein adjusting the data rate of the second data traffic includes decreasing the data rate of the second data traffic.

3. The method of claim 2, wherein decreasing the data rate of the second data traffic includes spreading out the second data traffic.

4. The method of claim 1, further comprising:
sending the first data traffic and the second data traffic to a data receiver of the DRAM; and
sending clock signals to a clock receiver of the DRAM.

5. The method of claim 4, wherein adjusting the data rate of the second data traffic reduces jitter between the data receiver and the clock receiver.

6. The method of claim 1, wherein the data rate of the second data traffic is adjusted based on a rule associated with the rate-of-change.

7. The method of claim 6, wherein the rule is at least partially based on a size of the second data traffic.

8. The method of claim 6, wherein the rule is accessible to the controller via a table.

9. The method of claim 8, wherein populating the table with the rule comprises:
sending data traffic of a particular size to the DRAM via a data bus at the adjusted data rate after the data bus has been idle for a particular time period, wherein a size of the second data traffic is approximately equal to the particular size;
measuring a voltage drift on a power bus coupled to the DRAM when the data traffic of the particular size is sent to the DRAM; and
populating the table with the rule in response to a determination that the voltage drift satisfies a drift threshold.

10. An apparatus comprising:
a processor; and
a memory storing instructions executable by the processor to perform operations comprising:
detecting a rate-of-change between first data traffic to be sent to a dynamic random access memory (DRAM) at a first time and second data traffic to be sent to the DRAM at a second time; and
adjusting a data rate of the second data traffic in response to a determination that the rate-of-change satisfies a threshold.

11. The apparatus of claim 9, wherein adjusting the data rate of the second data traffic includes decreasing the data rate of the second data traffic.

12. The apparatus of claim 11, wherein decreasing the data rate of the second data traffic includes spreading out the second data traffic.

13. The apparatus of claim 9, wherein the operations further comprise:
sending the first data traffic and the second data traffic to a data receiver of the DRAM; and
sending clock signals to a clock receiver of the DRAM.

14. The apparatus of claim 11, wherein adjusting the data rate of the second data traffic reduces jitter between the data receiver and the clock receiver.

15. The apparatus of claim 1, wherein the data rate of the second data traffic is adjusted based on a rule associated with the rate-of-change.

16. The apparatus of claim 15, wherein the rule is at least partially based on a size of the second data traffic.

17. The apparatus of claim 15, wherein the rule is accessible to the processor via a table.

18. The apparatus of claim 17, wherein the operations further comprise:
sending data traffic of a particular size to the DRAM via a data bus at the adjusted data rate after the data bus has been idle for a particular time period, wherein a size of the second data traffic is approximately equal to the particular size;
measuring a voltage drift on a power bus coupled to the DRAM when the data traffic of the particular size is sent to the DRAM; and
populating the table with the rule in response to a determination that the voltage drift satisfies a drift threshold.

19. A non-transitory computer-readable medium comprising instructions that, when executed by a processor, cause the processor to:
detect a rate-of-change between first data traffic to be sent to a dynamic random access memory (DRAM) at a first time and second data traffic to be sent to the DRAM at a second time; and
adjust a data rate of the second data traffic in response to a determination that the rate-of-change satisfies a threshold.

20. The non-transitory computer-readable medium of claim 19, wherein adjusting the data rate of the second data traffic includes decreasing the data rate of the second data traffic.

21. The non-transitory computer-readable medium of claim 19, further comprising instructions that, when executed by the processor, cause the processor to:
send the first data traffic and the second data traffic to a data receiver of the DRAM; and
send clock signals to a clock receiver of the DRAM.

22. The non-transitory computer-readable medium of claim 21, wherein adjusting the data rate of the second data traffic reduces jitter between the data receiver and the clock receiver.

23. The non-transitory computer-readable medium of claim 19, wherein the data rate of the second data traffic is adjusted based on a rule associated with the rate-of-change.

24. The non-transitory computer-readable medium of claim 23, wherein the rule is at least partially based on a size of the second data traffic.

25. The non-transitory computer-readable medium of claim 23, wherein the rule is accessible to the processor via a table.

26. The non-transitory computer-readable medium of claim 25, further comprising instructions that, when executed by the processor, cause the processor to:
send data traffic of a particular size to the DRAM via a data bus at the adjusted data rate after the data bus has been idle for a particular time period, wherein a size of the second data traffic is approximately equal to the particular size;
measure a voltage drift on a power bus coupled to the DRAM when the data traffic of the particular size is sent to the DRAM; and
populate the table with the rule in response to a determination that the voltage drift satisfies a drift threshold.

27. An apparatus comprising:
means for detecting a rate-of-change between first data traffic to be sent to a dynamic random access memory (DRAM) at a first time and second data traffic to be sent to the DRAM at a second time; and
means for adjusting a data rate of the second data traffic in response to a determination that the rate-of-change satisfies a threshold.

28. The apparatus of claim 27, wherein adjusting the data rate of the second data traffic includes decreasing the data rate of the second data traffic.

29. The apparatus of claim 27, further comprising:
means for sending the first data traffic and the second data traffic to a data receiver of the DRAM; and
means for sending clock signals to a clock receiver of the DRAM.

30. The apparatus of claim 29, wherein adjusting the data rate of the second data traffic reduces jitter between the data receiver and the clock receiver.
